(19) United States
(12) Patent Application Publication
(10) Pub. No.: US 2012/0319759 A1
(43) Pub. Date: Dec. 20, 2012

(54) SEMICONDUCTOR INTEGRATED CIRCUIT AND OPERATION CONTROL METHOD OF SEMICONDUCTOR INTEGRATED CIRCUIT

(75) Inventor: Norifumi Kobayashi, Kanagawa (JP)

(73) Assignee: Kabushiki Kaisha Toshiba, Tokyo (JP)

(21) Appl. No.: 13/416,359

(22) Filed: Mar. 9, 2012

(30) Foreign Application Priority Data
Jun. 15, 2011 (JP) 2011-133399

(51) Int. Cl. H03K 3/42

(52) U.S. Cl. 327/512

(57) ABSTRACT

According to an embodiment, a semiconductor integrated circuit has a control section configured to execute feedback control by regulating a control parameter of a circuit section based on a temperature or an operation speed of the circuit section so that the temperature is stabilized, a history register configured to store historical data including first historical data that are time series data of the temperature, and second historical data that are time series data of the control parameter, and effectiveness determining section configured to determine effectiveness of the feedback control from the historical data.

### CROSS REFERENCE TO RELATED APPLICATION

This application is based upon and claims the benefit of priority from the Japanese Patent Application No. 2011-133399, filed on Jun. 15, 2011; the entire contents of which are incorporated herein by reference.

### FIELD

An embodiment described herein relates generally to a semiconductor integrated circuit and an operation control method of the semiconductor integrated circuit.

### BACKGROUND

In order to realize reduction of power consumption of semiconductor integrated circuits mounted on various devices, various methods have been conventionally proposed and adopted. For example, there are VID (Voltage ID) which controls power supply voltage in accordance with an operation mode, and DPTC (Dynamic Process & Temperature Compensation) that regulates a voltage which drives a circuit in accordance with a temperature and a process.

For example, some of various semiconductor integrated circuits have characteristics that operation speeds of the circuits become high or low with a rise or reduction of the temperature of the semiconductor integrated circuits. In a semiconductor integrated circuit like this, feedback control is performed so as to reduce a power supply voltage VDD when the temperature of the semiconductor integrated circuit rises because the operation speed becomes high, and to increase the power supply voltage BDD conversely when the temperature of the semiconductor integrated circuit is reduced because the operation speed becomes low, whereby low power consumption can be realized while the performance of the semiconductor integrated circuit is kept.

However, when a feedback control system which takes the temperature parameter of a semiconductor integrated circuit taken into consideration like this is adopted, the state in which control is repeated, which reduces the power supply voltage VDD when the temperature of the semiconductor integrated circuit rises, and increases the power supply voltage VDD when the temperature of the semiconductor integrated circuit reduces, a so-called loop state in the control sometimes occurs.

In the case of a loop state like this, the feedback control system is brought into an oscillation state in which the temperature of the semiconductor integrated circuit becomes too high or too low, and under some circumstances, the problem arises that the temperature of the semiconductor integrated circuit exceeds an operation guaranteed range, and the semiconductor integrated circuit performs a malfunction, operation halt or the like.

### BRIEF DESCRIPTION OF THE DRAWINGS

FIG. 1 is a configuration diagram showing a configuration example of a semiconductor integrated circuit according to an embodiment;

FIG. 2 is a block diagram showing a configuration of a lower power consumption control program CP according to the embodiment;

FIG. 3 is a diagram showing an example of a table of an operation frequency level according to the embodiment;

FIG. 4 is a diagram showing an example of a table of a control level of a number of operation blocks according to the embodiment;

FIG. 5 is a flowchart showing a flow of storage processing of historical data according to the embodiment;

FIG. 6 is a diagram showing an example of the historical data which is stored in a history register 17 according to the embodiment;

FIG. 7 is a timing chart for explaining an example of control by the low power consumption control program CP according to the embodiment;

FIG. 8 is a flowchart showing an example of a flow of processing of the lower power consumption control program CP according to the embodiment;

FIG. 9 is a diagram showing an example of pattern data which is used in determination of effectiveness of feedback control by a power supply voltage control section 21, according to the embodiment;

FIG. 10 is a diagram showing an example of pattern data which is used in determination of effectiveness of feedback control by an operation frequency control section 22, according to the embodiment;

FIG. 11 is a diagram showing an example of pattern data which is used in determination of effectiveness of feedback control by an operation block control section 23, according to the embodiment;

FIG. 12 is a flowchart showing an example of a flow of processing of a temperature control program TP according to the embodiment;

FIG. 13 is a diagram showing an example of pattern data which is used in determination of effectiveness of feedback control of a heater 16, according to the embodiment; and

FIG. 14 is a diagram showing another example of pattern data which is used in determination of effectiveness of the feedback control of the heater 16, according to the embodiment.

### DETAILED DESCRIPTION

A semiconductor integrated circuit of an embodiment has a control section, a historical data register, and an effectiveness determining section. The control section regulates a first control parameter of a circuit section and executes first feedback control so that a temperature or an operation speed is stabilized, based on the temperature or the operation speed of the circuit section. The historical data register stores historical data including first historical data that are time series data of the aforesaid temperature or operation speed, and second historical data that are time series data of the aforesaid first control parameter. The effectiveness determining section determines effectiveness of the aforesaid first feedback control from the aforesaid historical data.

Hereinafter, an embodiment will be described with reference to the drawings.

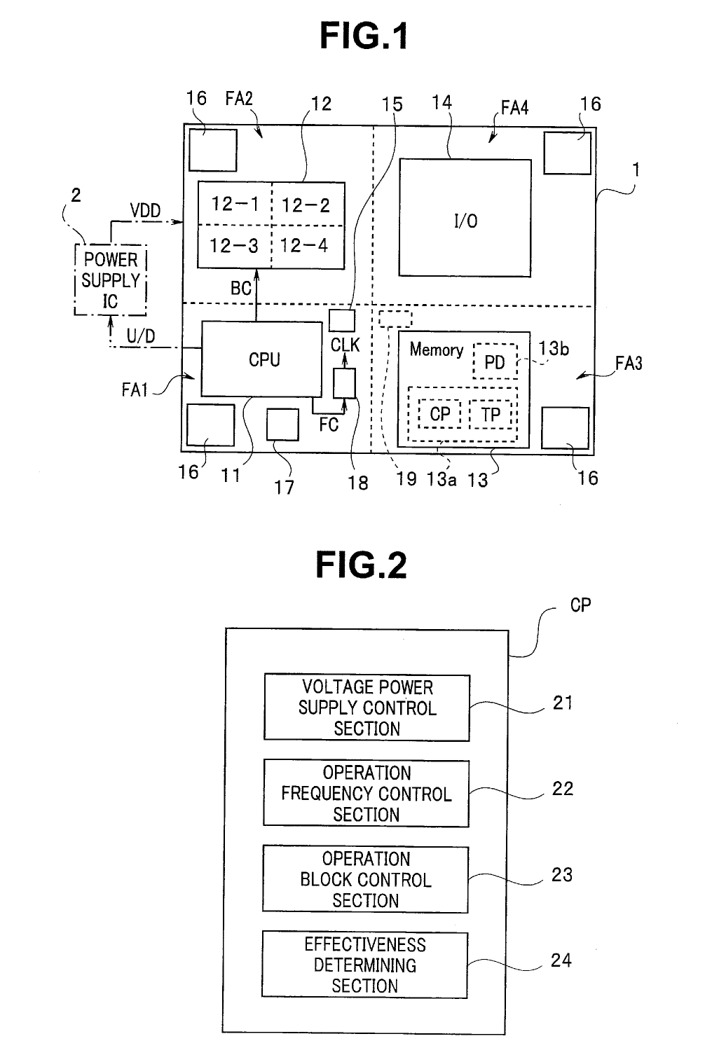

FIG. 1 is a configuration diagram showing a configuration example of a semiconductor integrated circuit according to the present embodiment. A semiconductor integrated circuit 1 is formed on a semiconductor substrate, and is configured as one semiconductor chip (hereinafter, simply called a chip). A power supply voltage VDD is supplied to the semiconductor integrated circuit 1 from a power supply IC 2. The power supply IC 2 is a different chip from the chip including the semiconductor integrated circuit 1.

FIG. 1 is an arrangement drawing showing schematic arrangement of various circuits on the chip where the semiconductor integrated circuit 1 is formed. The semiconductor integrated circuit 1 of the present embodiment mainly has four functional areas FA1, FA2, FA3 and FA4 as shown by the dotted lines. The functional area FA1 is an area of a central processing unit (hereinafter, called a CPU) 11. The functional area FA2 is an area of a logic processing unit 12 which performs a predetermined operation. The functional area FA3 is an area of a memory 13. The functional area FA4 is an area of an input/output unit (hereinafter, called an I/O unit) 14.

The power supply IC 2 changes the power supply voltage VDD which is supplied to the semiconductor integrated circuit 1 in response to a control signal U/D of UP or DOWN for controlling the power supply voltage VDD from the CPU 11. Here, upon reception of the control signal U indicating UP, the power supply IC 2 increases the power supply voltage VDD by one stage, and upon reception of the control signal D indicating DOWN, the power supply IC 2 reduces the power supply voltage VDD by one stage. The power supply voltage VDD is changed within the changeable range between predetermined upper and lower limit values. The control signal from the CPU 11 may be a level signal indicating a voltage level instead of the control signal U/D.

The CPU 11 of the area FA1 is a circuit unit configured to read and execute a program which is externally inputted or a program stored in the memory 13 of the area FA3. The logic processing unit 12 of the area FA2 is a circuit unit configured to include, for example, logic sections 12-1, 12-2, 12-3 and 12-4 configured to perform coding and decoding operations. The memory 13 of the area FA3 is a circuit unit configured to store programs or data temporarily or nontemporarily. The I/O unit 14 of the area FA4 is a circuit unit configured for the semiconductor integrated circuit 1 to transmit and receive signals to and from other devices, chips and the like.

The performance of the semiconductor integrated circuit 1 depends on a temperature, and therefore, control for keeping the temperature of the semiconductor integrated circuit 1 at a predetermined temperature is performed. For example, if the temperature of the semiconductor integrated circuit 1 is excessively reduced, a predetermined performance of the semiconductor integrated circuit 1 sometimes cannot be obtained. Accordingly, a temperature control program TP for keeping the temperature of the semiconductor integrated circuit 1 so that the temperature does not become a predetermined temperature Tth or lower is stored in a non-temporary, that is, nonvolatile storage area 13a of the memory 13, and is read and executed by the CPU 11. Furthermore, the memory 13 has a pattern data storage section 13b configured to store various pattern data which will be described later.

Further, a temperature sensor 15 is provided on the chip of the semiconductor integrated circuit 1 in order to detect the temperature of the semiconductor integrated circuit 1. The temperature sensor 15 as a temperature detector is, for example, a thermistor. A position of the temperature sensor 15 on the chip is determined by thermal analysis simulation of the chip. The temperature sensor 15 is arranged in a position where the temperature is the highest, a position or in the vicinity of a so-called hot spot, for example. In FIG. 1, the temperature sensor 15 is placed in a position substantially center of the chip and at a slightly lower left side near to the CPU 11.

The temperature of the semiconductor integrated circuit 1 may be detected by using change of the threshold voltage of one of the transistors in the semiconductor integrated circuit 1 without using the temperature sensor 15 such as a thermistor.

Further, the semiconductor integrated circuit 1 cannot exhibit a predetermined performance when the temperature thereof becomes low, and therefore, heaters 16 for preventing the semiconductor integrated circuit 1 from becoming the predetermined temperature Tth or lower are provided at a plurality of spots. In this case, the four heaters 16 are arranged in the corners of the chip as shown in FIG. 1.

Further, the semiconductor integrated circuit 1 has a historical data register (hereinafter, called a history register) 17 configured to store historical data. As will be described later, the historical data of the history register 17 is used in power supply voltage control, operation frequency control, operation block control and heater control of the semiconductor integrated circuit 1. A configuration of the history register 17 will be described later.

Further, the semiconductor integrated circuit 1 includes a frequency control section 18 configured to control a frequency F of a clock signal CLK which is supplied to all or individual circuits of the semiconductor integrated circuit 1. The frequency control section 18 changes the clock signal CLK which is supplied to each of the circuits in the semiconductor integrated circuit 1 so as to drive the semiconductor integrated circuit 1 with the clock signal CLK of the frequency F corresponding to a control signal FC for controlling the frequency F from the CPU 11.

The semiconductor integrated circuit 1 is a circuit for realizing a predetermined function, and the CPU 11 executes the program which realizes the predetermined function thereof, and also executes a low power consumption control program CP for low power consumption, by using the logic processing unit 12, the memory 13 and the I/O unit 14. The low power consumption control program CP is also stored in the non-volatile storage area 13a of the memory 13. The CPU 11 reads the low power consumption control program CP from the memory 13 and executes the low power consumption control program CP.

The temperature control program TP and the low power consumption control program CP described above are usually executed at all times when the semiconductor integrated circuit 1 is actuated.

In this case, control for preventing the temperature of the semiconductor integrated circuit 1 from being the predetermined temperature Tth or lower and control for low power consumption are performed by the CPU 11 executing the temperature control program TP and the low power consumption control program CP, but these controls may be realized by a hardware circuit or an exclusive CPU.

FIG. 2 is a block diagram showing a configuration of the low power consumption control program CP. The low power consumption control program CP includes respective control sections that are a power supply voltage control section 21, an operation frequency control section 22 and an operation block control section 23 of the semiconductor integrated circuit 1, and an effectiveness determining section 24.

The power supply voltage control section 21 is a processing program section configured to control the power supply voltage VDD which is supplied to the semiconductor integrated circuit 1 from the power supply IC 2. The power supply voltage control is performed by regulating the power supply voltage VDD as the control parameter based on the detected value, that is, a detected temperature Td of the temperature sensor 15 so that the temperature of the semiconductor integrated circuit 1 is stabilized. When the semiconductor integrated circuit 1 has the characteristic that the operation speed becomes high with rise of the temperature, the power supply voltage control section 21 performs feedback control to reduce the power supply voltage VDD when the detected temperature Td rises, and the power supply voltage control section 21 performs feedback control to increase the power supply voltage VDD when the detected temperature TD is reduced, because the operation speed of the semiconductor integrated circuit 1 becomes low. In some cases, the semiconductor integrated circuit 1 has the characteristic that the operation speed becomes low with rise of the temperature, but in the present embodiment, description is made with the case of the semiconductor integrated circuit 1 having the characteristic that the operation speed becomes high with rise of the temperature.

The operation frequency control section 22 is a processing section configured to control an operation frequencies F, that is, a frequency F of a clock signal CLK of all or each of the circuits of the semiconductor integrated circuit 1. The operation frequency control section 22 performs control by regulating the operation frequency F as a control parameter based on the detected temperature Td of the temperature sensor 15 so that the temperature of the semiconductor integrated circuit 1 is stabilized. The operation frequency control section 22 performs feedback control to reduce the operation frequency F when the detected temperature Td rises, and to increase the operation frequency F when the detected temperature Td reduces.

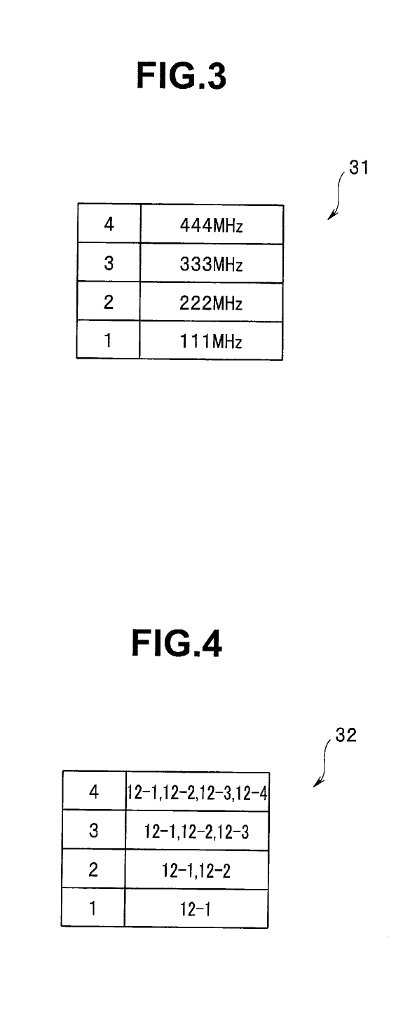

FIG. 3 is a diagram showing an example of a table of an operation frequency level. In an operation frequency table 31 shown in FIG. 3, four levels 1, 2, 3 and 4 correspond to 111 MHz, 222 MHz, 333 MHz and 444 MHz respectively. The CPU 11 supplies a control signal FC for controlling the operation frequency F to the frequency control section 18 in accordance with the detected temperature Td.

The operation block control section 23 is a processing section configured to control operations of the plurality of logic sections 12-1, 12-2, 12-3 and 12-4 in the logic processing unit 12. The operation block control section 23 performs control by regulating the number of operation blocks N (N is an integer, and any one of 1 to 4 in this case) as a control parameter based on the detected value of the temperature sensor 15 so that the temperature of the semiconductor integrated circuit 1 is stabilized. The operation block control section 23 performs feedback control so as to decrease the number of logic sections to be operated, that is, the number of operation blocks N when the temperature rises, and to increase the number of logic sections to be operated when the temperature lowers.

FIG. 4 is a diagram showing an example of a table of a control level of the number of operation blocks. In an operation block control table 32 shown in FIG. 4, the information of the blocks to be operated in the logic processing unit 12 is stored for each of four operation levels 1, 2, 3 and 4. The CPU 11 determines the operation level of the block control level 22 in accordance with the detected temperature Td detected by the temperature sensor 15, and supplies a control signal BC indicating the level for controlling the operation of each of the blocks to the logic processing unit 12. Supply of the power to each of the blocks is controlled in response to the control signal BC, and only the operation block which is designated by the control signal BC receives supply of the power and becomes operable.

The effectiveness determining section 24 is a processing section configured to determine effectiveness of feedback control from the historical data stored in the history register 17, as will be described later. The processing content of the effectiveness determining section 24 will be described later.

As described above, the semiconductor integrated circuit 1 is a circuit capable of executing the program which realizes a predetermined function, and the CPU 11 executes the low power consumption program CP for low power consumption while executing the program, and thereby, reduces the power consumption of the semiconductor integrated circuit 1.

Further, depending on the temperature of the semiconductor integrated circuit 1, a predetermined performance of the semiconductor integrated circuit 1 sometimes cannot be obtained. Thus, the semiconductor integrated circuit 1 compares the detected temperature Td and the predetermined threshold temperature Tth and controls drive of the heater 16 based on the comparison result so that the semiconductor integrated circuit 1 obtains a predetermined performance by executing the aforementioned temperature control program TP while executing the program that realizes the predetermined function.

Thereby, the semiconductor integrated circuit 1 reduces power consumption while keeping the predetermined performance of the semiconductor integrated circuit 1 by executing the low power consumption control program CP and the temperature control program TP while executing the program that realizes the predetermined function.

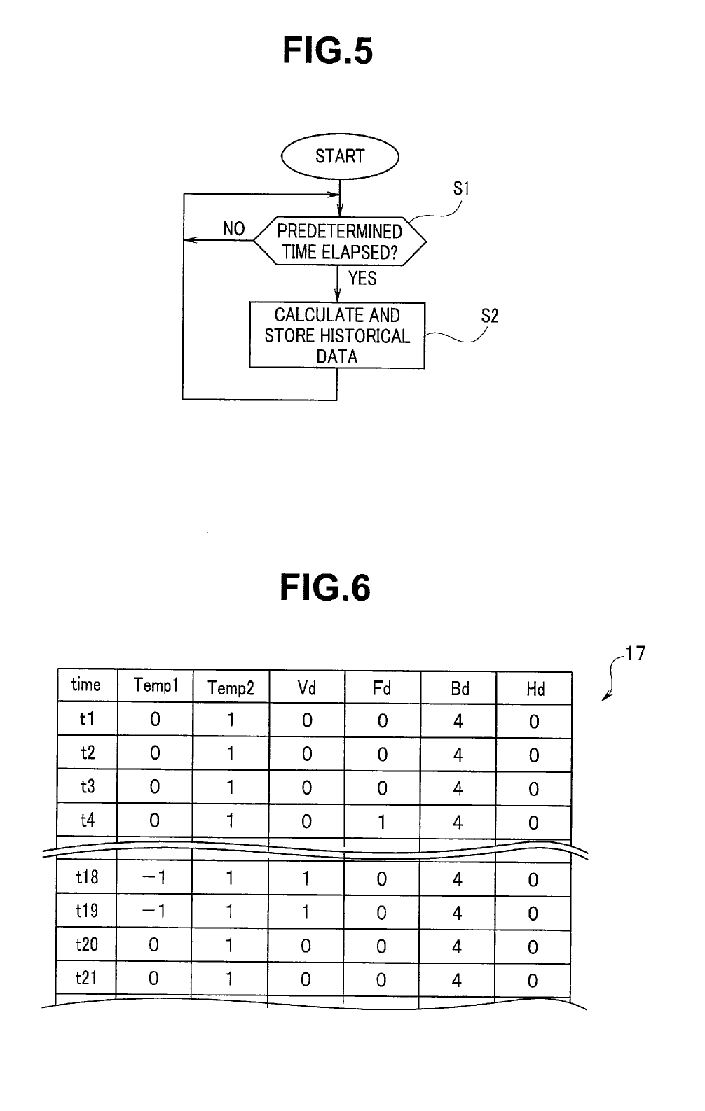

The low power consumption control program CP or the temperature control program TP includes storage processing of historical data into the history register 17 in part thereof. FIG. 5 is a flowchart showing a flow of storage processing of the historical data. The CPU 11 counts a time by a counter not illustrated, and determines whether or not a predetermined time tp elapses (S1). The predetermined time tp is, for example, 10 seconds. When the predetermined time tp does not elapse (S1: NO), the CPU 11 performs no processing. When the predetermined time tp elapses (S1: YES), the CPU 11 obtains historical data by calculation, and stores the historical data in the history register 17 (S2), and the process returns to S1.

Consequently, according to the processing of FIG. 5, the CPU 11 calculates historical data every predetermined time tp, and stores the historical data in the history register 17, and therefore, the historical data which is calculated and stored every predetermined time tp is stored in the history register 17.

Here, a configuration of the history register 17 will be described. FIG. 6 is a diagram showing an example of the historical data stored in the history register 17. Various historical data of the temperature, the power supply voltage, the operation frequency, and the number of operation blocks are stored in the history register 17. The history register 17 has the storage capacity capable of storing a predetermined amount (for example, an amount corresponding to five minutes) of the historical data at each predetermined time interval tp. Therefore, the historical data stored in the history register 17 is time series data of the temperature and the like.

In the history register 17 of FIG. 6, a time t1 is the latest time, and the latest historical data is stored in the history register 17 in correspondence with the time t1. A time t2 is a time ten seconds earlier than the time t1, the historical data obtained 10 seconds earlier than the time t1 is stored in the history register 17 in correspondence with the time t2. A time t3 is a time 10 seconds earlier than the time t2, and in the history register 17, the historical data obtained 10 seconds earlier than the time t2 is stored in correspondence with the time t3. In this manner, the historical data is stored in the history register 17.

During execution of the low power consumption control program CP, the CPU 11 stores the historical data including historical data Temp1 and Temp2 of the temperature, historical data Vd of the power supply voltage, historical data Fd of the operation frequency, historical data Bd of the number of operation blocks, and historical data Hd indicating the operation of the heater 16 in the history register 17.

The CPU 11 performs storage control of the historical data so as to discard the historical data by the amount exceeding the storage capacity of the history register 17, and to retain only the latest historical data. In this case, in the history register 17, only the historical data corresponding to the latest five minutes is stored.

There are two kinds of historical data of the temperature. One is tendency data Temp1 which indicates tendency to rise or lower of the detected temperature Td which is detected by the temperature sensor 15. The other one is threshold comparison data Temp2 which indicates whether or not the detected temperature Td of the temperature sensor 15 is the predetermined threshold temperature Tth or lower.

The tendency data Temp1 is data indicating whether the detected temperature Td detected by the temperature sensor 15 exceeds, is the same, or is below the detected temperature of the previous time (10 seconds before in this case). When the detected temperature Td exceeds the detected temperature of the previous time, the CPU 11 sets Temp1 as “+1”. When the detected temperature Td is the same as the detected temperature of the previous time, the CPU 11 sets Temp1 as “0”. When the detected temperature Td is below the detected temperature of the previous time, the CPU 11 sets Temp1 as “−1”.

The threshold value comparison data Temp2 is data indicating whether or not the detected temperature Td is not higher than the threshold temperature Tth by comparison of the detected temperature Td detected by the temperature sensor 15 and the predetermined threshold temperature Tth(for example, 10° C.). The CPU 11 sets the threshold value comparison data Temp2 as “0” when the detected temperature Td is not higher than the predetermined threshold temperature Tth, and sets the threshold value comparison data Temp2 as “1” when the detected temperature Td exceeds the threshold temperature Tth.

The CPU 11 sets the historical data Vd of the power supply voltage to “1” when the power supply voltage VDD is increased by the feedback control of the power supply voltage control section 21, sets the historical data Vd to “0” when the power supply voltage VDD is not changed, and sets the historical data Vd to “−1” when the power supply voltage VDD is reduced.

The CPU 11 sets the historical data Fd of the operation frequency to “1” when the frequency F of a clock signal, that is, the operation frequency F is increased by the feedback control of the operation frequency control section 22, and sets the historical data Fd to “0” when the operation frequency F is not changed, and sets the historical data Fd to “−1” when the operation frequency F is reduced.

The CPU 11 sets the historical data Bd of the number of operation blocks to the number of operation blocks N which is determined by the feedback control of the operation block control section 23. For example, when the number of operation blocks is four, the historical data Bd is set as “4”, and when the number of operation blocks is three, the historical data Bd is set as “3”.

The CPU 11 sets the historical data Hd indicating the operation of the heater 16 to “1” when the heater 16 is on by the temperature control program TP, and sets the historical data Hd to “0” when the heater 16 is off.

As described above, in the storage processing (S2) of the historical data, the historical data are calculated, and stored in the history register 17. Consequently, the history register 17 is a historical data register which stores the historical data including the historical data of the temperature, and the historical data of the respective control parameters.

Next, processing of the low power consumption control program CP will be described.

When the low power consumption control program CP is executed, the CPU 11 first performs feedback control which regulates the power supply voltage VDD as the control parameter, based on the detected temperature Td of the temperature sensor 15 by the power supply voltage control section 21.

In the feedback control by the power supply voltage control section 21, the power supply voltage VDD is controlled in such a manner that, for example, when the change of the detected temperature Td is a change which is an increase by a predetermined amount ΔT or more, the power supply voltage VDD is reduced by one stage, when the change of the detected temperature Td is a change which is a decrease by the predetermined amount ΔT or more, the power supply voltage VDD is increased by one stage, and when the change of the detected temperature Td is a change of less than the predetermined amount ΔT, the power supply voltage VDD is kept.

When the temperature of the semiconductor integrated circuit 1 becomes stable by the feedback control of the power supply voltage, the low power consumption control program CP continues the feedback control by the power supply voltage control section 21, but when the temperature of the semiconductor integrated circuit 1 is not stabilized, the low power consumption control program CP shifts to the feedback control by the operation frequency control section 22.

When the temperature of the semiconductor integrated circuit 1 becomes stable by the feedback control by the operation frequency control section 22, the low power consumption control program CP continues the feedback control by the operation frequency control section 22, but when the temperature of the semiconductor integrated circuit 1 does not become stable, the low power consumption control program CP shifts to the feedback control by the operation block control section 23.

In each of the feedback controls, the control variable of the power supply voltage VDD or the like which is the control parameter is changed in proportion with the change amount of the detected temperature Td.

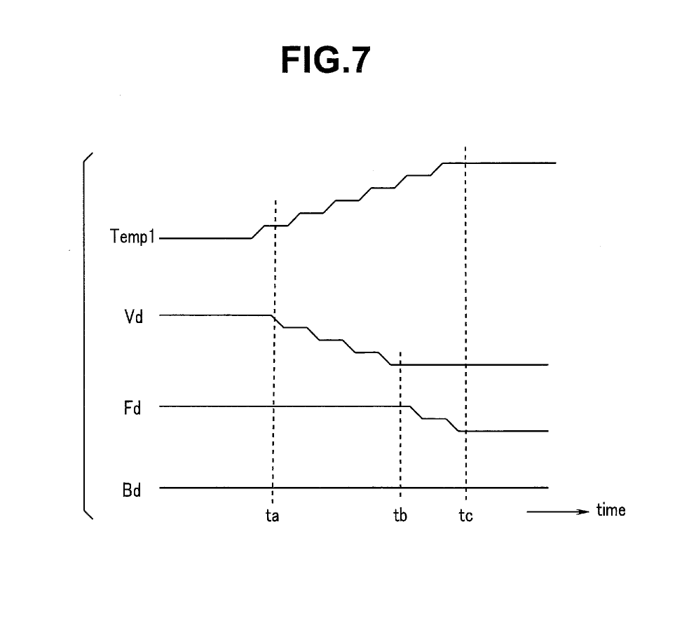

FIG. 7 is a timing chart for explaining an example of the control according to the low power consumption control program CP. In the example shown in FIG. 7, the tendency data Temp1 rises by rise of the detected temperature Td of the temperature sensor 15. The power supply voltage VDD is reduced by one stage by the power supply voltage control section 21 at a time ta, after which, rise of the detected temperature Td continues, and the temperature of the semiconductor integrated circuit 1 does not become stable. Therefore, at a time tb, the control shifts to the feedback control by the operation frequency control section 22 from that by the power supply voltage control section 21. Thereafter, it is shown that the temperature of the semiconductor integrated circuit 1 is stabilized at a time tc. In FIG. 7, the temperature of the semiconductor integrated circuit 1 is stabilized by the feedback control by the operation frequency control section 22, and therefore, the control does not shift to the operation block feedback control of the operation block control section 23.

Here, as an example, the low power consumption control program CP controls the temperature of the semiconductor integrated circuit 1 by changing the control parameters in the sequence of the power supply voltage control, the operation frequency control and the operation block control as an example, but the sequence of the change of the control parameters, in other words, the priority may be in the sequence different from the above sequence.

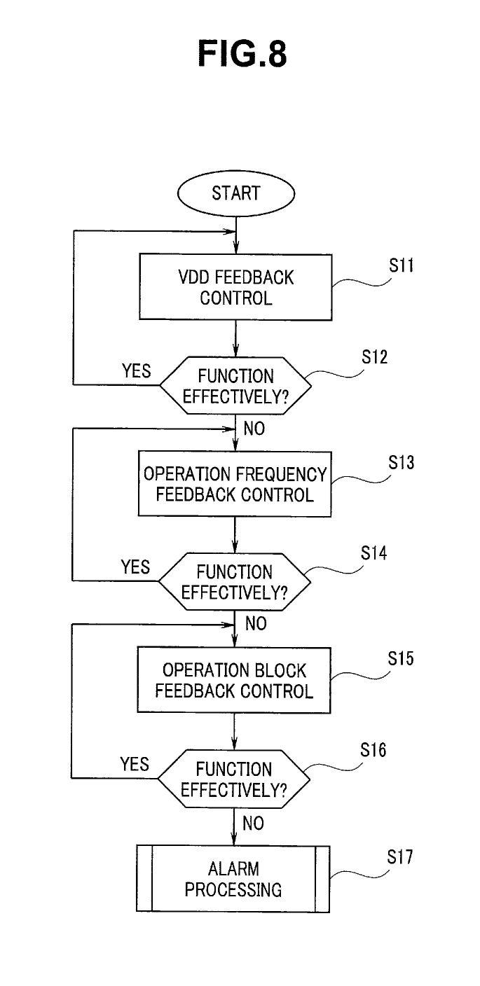

FIG. 8 is a flowchart showing an example of a flow of the processing of the low power consumption control program CP.

In the low power consumption control program CP, the CPU 11 executes the feedback control by the power supply voltage control section 21 (S11). In the feedback control, the control to increase or decrease, or keep the power supply voltage VDD is performed based on the detected temperature Td of the temperature sensor 15. Control of changing or keeping the power supply voltage VDD which is the control parameter is executed so that the detected temperature Td is stabilized with the detected temperature Td as input. If the feedback control effectively functions, the temperature of the semiconductor integrated circuit 1 is usually stabilized.

However, when the state in which the control is repeated, which reduces the power supply voltage VDD when the detected temperature Td rises, and increases the power supply voltage VDD when the detected temperature Td reduces, a so-called loop state in the control may occur, the temperature of the semiconductor integrated circuit 1 continues to rise, and the situation in which the temperature of the semiconductor integrated circuit 1 exceeds a predetermined temperature compensation range can occur.

Thus, it is determined whether or not the feedback control effectively functions, during feedback control by the power supply voltage control section 21 (S12). The processing of S12 is executed in the effectiveness determining section 24 which determines the effectiveness of the feedback control from the historical data stored in the history register 17.

The determination of the effectiveness of the feedback control by the power supply voltage control section 21 is performed, more specifically, by storing the pattern data showing the state in which the feedback control by the power supply voltage control section 21 does not effectively function, in the pattern data storage section 13b of the memory 13 in advance, and comparing the historical data stored in the history register 17 and the pattern data thereof during the feedback control by the power supply voltage control section 21. In more detail, in the determination of the effectiveness of the feedback control, matching of the pattern data and the historical data is determined by pattern matching, and when the pattern data and the historical data match each other, the feedback control is determined as ineffective, whereas when the pattern data and the historical do not match each other, the feedback control is determined as effective.

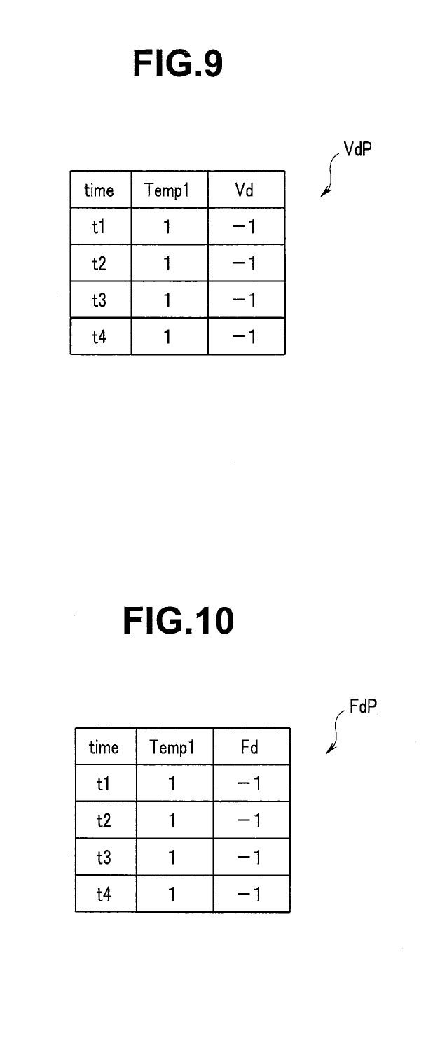

FIG. 9 is a diagram showing an example of the pattern data which is used in determination of effectiveness of the feedback control by the power supply voltage control section 21. Pattern data VdP, which is used in determination of effectiveness of the feedback control, includes a plurality of tendency data Temp1 and a plurality of historical data Vd of the power supply voltage, which are respectively time series data. In FIG. 9, the pattern data VdP is configured by the four tendency data Temp1 which continue to each other temporally, and four historical data Vd of the power supply voltage which are control parameters and correspond to the tendency data Temp1.

The tendency data Temp1 which is obtained 30 seconds before (t4) is “1”, and therefore, indicates that the temperature of the semiconductor integrated circuit 1 rises. The corresponding power supply voltage historical data Vd is “−1”, and therefore, indicates that the power supply voltage VDD is reduced by one stage. Further, the tendency data Temp1 and the historical data Vd of the power supply voltage which are obtained 20 seconds before (t3), 10 seconds before (t2) and of at the latest time (t1) are the same, and therefore, the data pattern VdP indicates that with the rise of the detected temperature Td, the power supply voltage VDD is continuously reduced, but the temperature of the semiconductor integrated circuit 1 is not stabilized. In other words, the data pattern VdP as shown in FIG. 9 are the data indicating the state in which the feedback control by the power supply voltage control section 21 does not effectively function.

Consequently, it is determined whether or not the latest historical data matches the data pattern VdP by pattern matching, during execution of the feedback control by the power supply voltage control section 21, whereby it can be determined whether or not the feedback control by the power supply voltage control section 21 effectively functions.

When the feedback control by the power supply voltage control section 21 effectively functions (S12: YES), the processing returns to S11, and when the feedback control by the power supply voltage control section 21 does not effectively function (S12: NO), that is, when the feedback control by the power supply voltage control section 21 is determined as ineffective, the processing shifts to the feedback control by the operation frequency control section 22 (S13).

In the feedback control by the operation frequency control section 22, control which increase or decrease or keeps the operation frequency F is performed based on the detected temperature Td of the temperature sensor 15 as described above. Control of changing or keeping the operation frequency F which is the control parameter is executed so that the detected temperature Td is stabilized with the detected temperature Td as input. If the operation frequency feedback control effectively functions, the temperature of the semiconductor integrated circuit 1 is usually stabilized, but here, a so-called loop state in the control occurs, the temperature of the semiconductor integrated circuit 1 continues to rise, and the case can occur, in which the temperature of the semiconductor integrated circuit 1 exceeds the predetermined temperature compensation range.

Thus, during feedback control by the operation frequency control section 22, it is determined whether or not the feedback control by the operation frequency control section 22 effectively functions (S14). The processing of S14 is executed in the effectiveness determining section 24 which determines effectiveness of feedback control from the historical data stored in the history register 17.

Determination of effectiveness of the feedback control by the operation frequency control section 22 is also performed, more specifically, by storing the pattern data showing the state in which the feedback control by the operation frequency control section 22 does not effectively function in the pattern data storage section 13b of the memory 13 in advance, and determining whether or not the historical data stored in the history register 17 matches the pattern data by pattern matching during the feedback control by the operation frequency control section 22, similarly to the determination of the effectiveness of the feedback control by the power supply voltage control section 21 described above.

FIG. 10 is a diagram showing an example of pattern data which is used in determination of effectiveness of feedback control by the operation frequency control section 22. Pattern data FdP which is used in determination of effectiveness of the feedback control by the operation frequency control section 22 includes a plurality of tendency data Temp1 and a plurality of historical data Fd of the operation frequency, which are time series data respectively. In FIG. 10, the pattern data FdP is configured by four tendency data Temp1 which temporally continue, and four historical data Fd of the operation frequency which correspond to the tendency data Temp1 and are control parameters.

As in FIG. 9, in FIG. 10, the tendency data Temp1 which is obtained 30 seconds before (t4) is “1”, and therefore, indicates that the temperature of the semiconductor integrated circuit 1 rises, and the corresponding historical data Fd of the operation frequency is “−1”, and therefore, indicates the operation frequency F is reduced by one stage. Further, the tendency data Temp1 and the historical data Fd of the operation frequency F which are obtained 20 seconds before (t3), 10 seconds before (t2), and at the latest (t1) time are the same, and therefore, the data pattern FdP indicates that with rise of the detected temperature Td, the operation frequency F is continuously reduced, but the temperature of the semiconductor integrated circuit 1 is not stabilized. In other words, the data pattern FdP as shown in FIG. 10 is the data which shows the state in which the feedback control by the operation frequency control section 22 does not effectively function.

Consequently, it can be determined whether or not the feedback control by the operation frequency control section 22 effectively functions by determining whether or not the latest historical data matches the data pattern FdP during execution of the feedback control by the operation frequency control section 22.

When feedback control by the operation frequency control section 22 effectively functions (S14: YES), the processing returns to S13, whereas when the feedback control by the operation frequency control section 22 does not effectively function (S14: NO), the processing shifts to operation block feedback control by the operation block control section 23 (S15).

In the feedback control by the operation block control section 23, control of increasing or decreasing or keeping the number of operation blocks N is performed based on the detected temperature Td of the temperature sensor 15 as described above. With the detected temperature Td as input, control of changing or keeping the number of operation blocks N which is a control parameter is executed so that the detected temperature Td is stabilized. When feedback control by the operation block control section 23 effectively functions, the temperature of the semiconductor integrated circuit 1 is usually stabilized, but in this case, the situation can occur, in which a so-called loop state in control occurs, the temperature of the semiconductor integrated circuit 1 continues to rise, and the temperature of the semiconductor integrated circuit 1 exceeds the predetermined temperature compensation range.

Thus, it is determined whether or not feedback control by the operation block control section 23 effectively functions, during the feedback control by the operation block control section 23 (S16). The processing of S16 is executed in the effectiveness determining section 24 which determines effectiveness of feedback control from the historical data stored in the history register 17.

Determination of effectiveness of the feedback control by the operation block control section 23 is also performed, more specifically by storing pattern data indicating that the feedback control by the operation block control section 23 does not effectively function in the pattern data storage section 13b of the memory 13 in advance, and determining whether or not the historical data stored in the history register 17 matches the pattern data by pattern matching during the feedback control by the operation block control section 23, similarly to the determination of the effectiveness of the feedback control by the power supply voltage control section 21 and the feedback control by the operation frequency control section 22 which are described above.

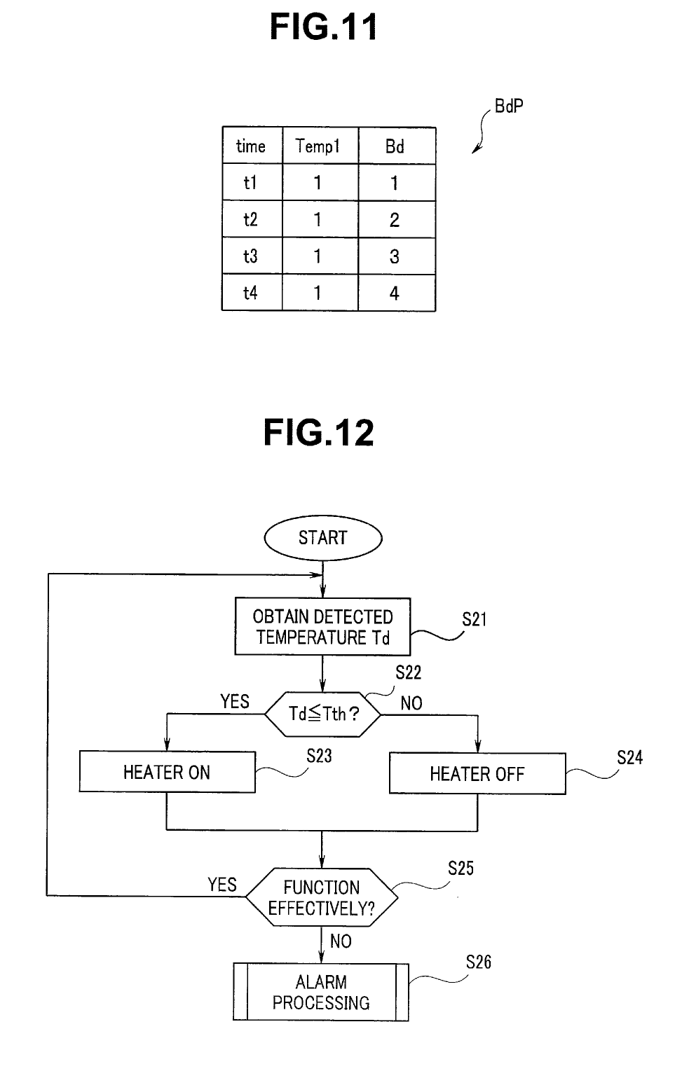

FIG. 11 is a diagram showing an example of the pattern data which is used in the determination of the effectiveness of the feedback control by the operation block control section 23. Pattern data BdP which is used in determination of the effectiveness of the feedback control by the operation block control section 23 includes a plurality of tendency data Temp1 and a plurality of historical data BD of the number of operation blocks, which are respectively time series data. In FIG. 11, the pattern data BdP is configured by four tendency data Temp1 which temporally continue and four historical data Bd of the number of operation blocks which correspond to the tendency data Temp1 and are control parameters.

In FIG. 11, as in FIGS. 9 and 10, the tendency data Temp1 which is obtained 30 seconds before (t4) indicates that the temperature does not rise, and the corresponding historical data Bd of the number of operation blocks is “4”. However, the tendency data Temp1 which is obtained 20 seconds before (t3) is “1”, and therefore, indicates that the temperature of the semiconductor integrated circuit 1 rises, and the corresponding number of operation blocks N is “3”, and therefore, indicates that the number of operation blocks is decreased by one. Further, the tendency data Temp1 and the number of operation blocks N which are obtained 10 seconds before (t2) and at the latest time (t1) also indicate the same tendency as that obtained 20 seconds before. The pattern data BdP indicates that the number of operation blocks N is continuously decreased with rise of the detected temperature Td, but the temperature of the semiconductor integrated circuit 1 is not stabilized. In other words, the pattern data BdP as shown in FIG. 11 is the data showing the state in which the feedback control by the operation block control section 23 does not function effectively.

Consequently, during execution of the feedback control by the operation block control section 23, it is determined whether or not the latest historical data matches the pattern data BdP by pattern matching, whereby it can be determined whether or not the feedback control by the operation block control section 23 effectively functions.

When the feedback control by the operation block control section 23 effectively functions (S16: YES), the processing returns to S15, and when feedback control by the operation block control section 23 does not effectively function (S16: NO), the processing shifts to alarm processing (S17).

Alarm processing includes warning display or the like to a user. By the warning display or the like, the user can know that the temperature of the semiconductor integrated circuit 1 exceeds the operation guaranteed range, and a malfunction, operation halt and the like of the chip may occur, and therefore, the user can take measures such as stopping the program under execution.

Next, processing of the temperature control program TP will be described. FIG. 12 is a flowchart showing an example of a flow of the processing of the temperature control program TP.

In the temperature control program TP, the CPU 11 obtains the detected temperature Td from the output of the temperature sensor 15 (S21), and determines whether or not the detected temperature Td is a predetermined threshold value Tth, for example, 10° C., or lower(S22). When the detected temperature Td is the predetermined threshold value Th or lower (S22: YES), the CPU 11 turns on the heater 16 (S23). When the detected temperature Td is not the predetermined threshold value Tth or lower (S22: NO), the CPU 11 turns off the heater 16 (S24).

Subsequently, feedback control (S21 to S24) is performed by the heater 16 being turned on and off based on the detected temperature Td, control is usually performed so that the temperature of the semiconductor integrated circuit 1 does not become the predetermined threshold value Tth or lower, but immediately after operation of the semiconductor integrated circuit 1, immediately after the operation from the dormant state, or due to the other causes, the situation can arise, in which the temperature of the semiconductor integrated circuit 1 continues to lower, and the performance of the semiconductor integrated circuit 1 cannot be ensured.

Thus, during feedback control of the heater 16 based on the detected temperature Td, it is determined whether or not the feedback control effectively functions (S25).

The determination of the effectiveness of the feedback control of the heater 16 is also performed, more specifically by storing the pattern data in which the feedback control of the heater 16 does not effectively function in the pattern data storage section 13b of the memory 13 in advance and determining whether or not the historical data stored in the history register 17 matches the pattern data, during feedback control of the heater 16 based on the detected temperature Td, similarly to the determination of the effectiveness of each of the feedback controls described above.

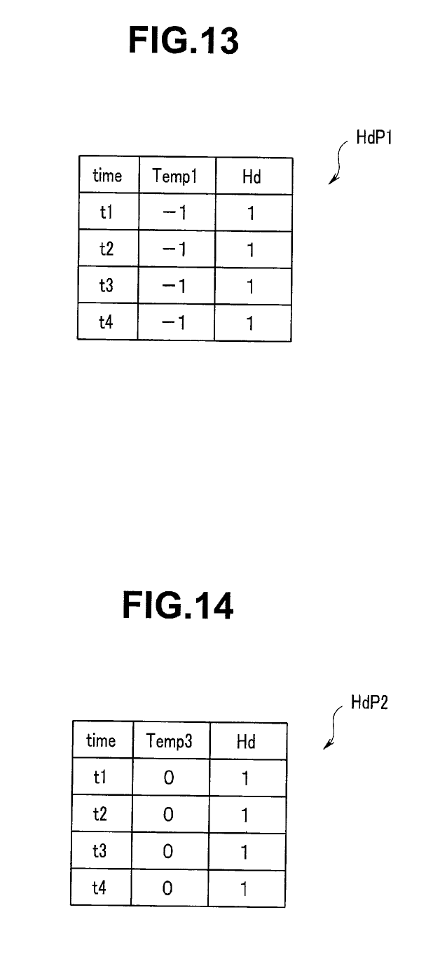

FIG. 13 is a diagram showing an example of the pattern data which is used in determination of the effectiveness of the feedback control of the heater 16. Pattern data HdP1 which is used in determination of the effectiveness of the feedback control of the heater 16 includes a plurality of tendency data Temp1 and a plurality of historical data Hd showing the operation of the heater 16, which are time series data respectively. In FIG. 13, the data pattern HdP1 is configured by four continuing tendency data Temp1, and the historical data Hd of the heater 16 which correspond to the tendency data Temp1 and are control parameters. The historical data Hd is “1” when the heater 16 is on, and is “0” when the heater 16 is off.

In FIG. 13, the tendency data Temp1 which is obtained 30 seconds before (t4) is “−1”, and therefore, indicates that the temperature of the semiconductor integrated circuit 1 lowers, and the corresponding historical data Hd indicates “1”, that is, indicates that the heater 16 is turned on. Further, the tendency data Temp1 and the historical data Hd, which are obtained 20 seconds before (t3), 10 seconds before (t2) and at the latest time (t1) are also the same, and therefore, the pattern data HdP1 indicates that with reduction in the detected temperature Td, the heater 16 is continuously turned on, but the temperature of the semiconductor integrated circuit 1 is not stabilized. In other words, the pattern data HdP1 as shown in FIG. 13 is the data which indicates the state in which the feedback control of the heater 16 does not effectively function.

FIG. 14 is a diagram showing another example of the pattern data which is used in determination of the effectiveness of the feedback control of the heater 16. A data pattern HdP2 which is used in determination of the effectiveness of the feedback control of the heater 16 includes a plurality of tendency data Temp3 and a plurality of historical data Hd of the heater 16, which are time series data respectively. The tendency data Temp3 indicates whether or not the detected temperature Td is the predetermined threshold value Tth, for example, 10° C., or lower, “0” indicates that the detected temperature Td is 10° C. or lower, and “1” indicates that the detected temperature Td exceeds 10° C.

In FIG. 14, the pattern data HdP2 is configured by the four continuing tendency data Temp3 and the historical data Hd of the heater 16 which correspond to the tendency data Temp3 and are control parameters.

In FIG. 14, the tendency data Temp3 which is obtained 30 seconds before (t4) is “0”, and therefore, indicates that the temperature of the semiconductor integrated circuit 1 is 10° C. or lower, and the corresponding historical data Hd indicates “1”, that is, indicates that the heater 16 is turned on. Further, the tendency data Temp3 and the historical data Hd, which are obtained 20 seconds before (t3), 10 seconds before (t2) and at the latest time (t1) are also the same, and therefore, the pattern data HdP2 indicates that the detected temperature Td is the predetermined threshold value Trh or lower, and the heater 16 is continuously turned on, but the temperature of the semiconductor integrated circuit 1 does not exceed the predetermined threshold value Tth. In other words, the pattern data HdP2 as shown in FIG. 14 is the data which indicates the state in which the feedback control of the heater 16 does not effectively function.

Consequently, during execution of the feedback control of the heater 16, it is determined whether or not the latest continuous history data match the pattern data HdP1 or HdP2, whereby it can be determined whether or not the feedback control of the heater 16 effectively functions or not.

When the feedback control of the heater 16 effectively functions (S25: YES), the processing returns to S21, and when the feedback control of the heater 16 does not effectively functions (S25: NO), the processing shifts to alarm processing (S26). The alarm processing of S26 is the same as S17 of the alarm processing of FIG. 8.

As described above, by the control program CP and the temperature control program TP, the case in which the feedback control under execution does not effectively function is determined from the predetermined historical data, and feedback control by the other control parameters is performed. As a result, according to the aforementioned semiconductor integrated circuit, the semiconductor integrated circuit can be prevented from performing a malfunction, operation halt and the like by being brought into the oscillation state in which the temperature of the semiconductor integrated circuit 1 becomes too high or too low.

The historical data which is stored in the history register may be data themselves of the detected temperature Td, the power supply voltage value, the drive frequency, the drive block number and the like, instead of the tendency of rise or reduction from the previous value, the number of stages and the like as described above.

Furthermore, in the aforementioned embodiment, the temperature by the temperature sensor is detected, and each feedback control is performed based on the detected temperature, but instead of the temperature, the operation speed of the circuit section is detected from the delay amount of the path between the predetermined circuit elements, or the like, and each feedback control may be performed based on the detected operation speed. This is because, in a semiconductor integrated circuit, a so-called junction temperature reduces if the temperature reduces, and the operation speed of the semiconductor integrated circuit changes.

In such a case, in order to measure the operation speed of the semiconductor integrated circuit, a frequency counter 19 may be provided instead of the temperature sensor 15 as shown by the dotted line in FIG. 1, and the operation frequency may be detected, whereby the operation speed of the circuit section may be detected.

While certain embodiments have been described, these embodiments have been presented by way of example only, and are not intended to limit the scope of the inventions. Indeed, the novel methods and circuits described herein may be embodied in a variety of other forms; furthermore, various omissions, substitutions and changes in the form of the methods and circuits described herein may be made without departing from the spirit of the inventions. The accompanying claims and their equivalents are intended to cover such forms or modifications as would fall within the scope and spirit of the inventions.

What is claimed is:

1. A semiconductor integrated circuit, comprising:
a control section configured to execute first feedback control by regulating a first control parameter of a circuit section based on a temperature or an operation speed of the circuit section so that the temperature or the operation speed is stabilized;
a historical data register configured to store historical data including first historical data that are time series data of the temperature or the operation speed, and second historical data that are time series data of the first control parameter; and
an effectiveness determining section configured to determine effectiveness of the first feedback control from the historical data.

2. The semiconductor integrated circuit according to claim 1,
wherein the control section can also execute second feedback control by regulating a second parameter, and
the control section executes the second feedback control instead of the first feedback control when the effectiveness determining section determines that the first feedback control is not effective.

3. The semiconductor integrated circuit according to claim 1,
wherein the effectiveness determining section determines effectiveness of the first feedback control by comparing pattern data indicating a state in which the first feedback control does not effectively function and the historical data.

4. The semiconductor integrated circuit according to claim 3,
wherein the effectiveness determining section determines matching of the pattern data and the historical data, and determines that the first feedback control is not effective when the pattern data and the historical data match each other, whereas when the pattern data and the historical data do not match each other, the effectiveness determining section determines that the first feedback control is effective.

5. The semiconductor integrated circuit according to claim 4,
wherein the effectiveness determining section determines matching of the pattern data and the historical data by pattern matching.

6. The semiconductor integrated circuit according to claim 1,
wherein the first control parameter is a power supply voltage of the circuit section, an operation frequency of the circuit section, or a number of operation blocks of a plurality of circuit blocks included in the circuit section.

7. The semiconductor integrated circuit according to claim 2,
wherein the first control parameter is one parameter out of a power supply voltage of the circuit section, an operation frequency of the circuit section, and a number of operation blocks of a plurality of circuit blocks included in the circuit section, and
the second control parameter is a parameter other than the one parameter out of the power supply voltage of the circuit section, the operation frequency of the circuit section and the number of operation blocks.

8. The semiconductor integrated circuit according to claim 1, further comprising:
a heater configured to be provided on a semiconductor chip mounted with the semiconductor integrated circuit,
wherein the control section controls the heater so that the temperature of the circuit section does not become a predetermined temperature or lower.

9. The semiconductor integrated circuit according to claim 1, further comprising:
a temperature sensor configured to be provided on a semiconductor chip mounted with the semiconductor integrated circuit,
wherein the temperature of the circuit section is detected by the temperature sensor.

10. The semiconductor integrated circuit according to claim 1, further comprising:
a frequency counter configured to be provided on a semiconductor chip mounted with the semiconductor integrated circuit,
wherein an operation speed of the circuit section is detected by the frequency counter.

11. An operation control method of a semiconductor integrated circuit, comprising:
executing first feedback control by regulating a first control parameter of the semiconductor integrated circuit based on a temperature or an operation speed of a circuit section of the semiconductor integrated circuit so that the temperature or the operation speed is stabilized;
storing, in a history data register, historical data including first historical data that are time series data of the temperature or the operation speed, and second historical data that are time series data of the first control parameter; and
determining effectiveness of the first feedback control from the historical data.

12. The operation control method of a semiconductor integrated circuit according to claim 11, further comprising:
executing second feedback control by regulating a second parameter based on the temperature or the operation speed, from the first feedback control, when it is determined that the first feedback control is not effective.

13. The operation control method of a semiconductor integrated circuit according to claim 11,
wherein the effectiveness of the first feedback control is determined by comparing pattern data indicating a state in which the first feedback control does not effectively function, and the historical data.

14. The operation control method of a semiconductor integrated circuit according to claim 13,
wherein matching of the pattern data and the historical data is determined, and when the pattern data and the historical data match each other, it is determined that the first feedback control is not effective, whereas when the pattern data and the historical data do not match each other, the first feedback control is determined as effective.

15. The operation control method of a semiconductor integrated circuit according to claim 14,
wherein matching of the pattern data and the historical data is determined by pattern matching.

16. The operation control method of a semiconductor integrated circuit according to claim 11,
wherein the first control parameter is a power supply voltage of the circuit section, an operation frequency of the circuit section, or a number of operation blocks of a plurality of circuit blocks included in the circuit section.

17. The operation control method of a semiconductor integrated circuit according to claim 12,
wherein the first control parameter is one parameter out of a power supply voltage of the circuit section, an operation frequency of the circuit section, and a number of operation blocks of a plurality of circuit blocks included in the circuit section, and
the second control parameter is a parameter other than the one parameter out of the power supply voltage of the circuit section, the operation frequency of the circuit section and the number of operation blocks.

18. The operation control method of a semiconductor integrated circuit according to claim 11, further comprising:
controlling a heater provided on a semiconductor chip mounted with the semiconductor integrated circuit so that the temperature of the circuit section does not become a predetermined temperature or lower.

19. The operation control method of a semiconductor integrated circuit according to claim 11,
wherein the temperature of the circuit section is detected by a temperature sensor that is provided on a semiconductor chip mounted with the semiconductor integrated circuit.

20. The operation control method of a semiconductor integrated circuit according to claim 11,
wherein an operation speed of the circuit section is detected by a frequency counter provided on a semiconductor chip mounted with the semiconductor integrated circuit.
